(19) United States
(12) Patent Application Publication
(10) Pub. No.: US 2013/0285019 A1
(43) Pub. Date: Oct. 31, 2013

(54) FIELD EFFECT TRANSISTOR AND METHOD OF FABRICATING THE SAME

(71) Applicants: SAMSUNG ELECTRONICS CO., LTD., Suwon-si (KR); POSTECH ACADEMY-INDUSTRY FOUNDATION, Pohang-si (KR)

(72) Inventors: Dongwon KIM, Seongnam-si (KR); Dae Mann Kim, Seoul (KR); Yoon-Ha Jeong, Pohang-si (KR); Sooyoung Park, Pohang-si (KR); Chan-Hoon Park, Pohang-si (KR); Rock-Hyun Baek, Albany, NY (US); Sang-Hyun Lee, Pohang-si (KR)

(73) Assignees: Postech Academy-Industry Foundation, Pohang-si (KR); Samsung Electronics Co., Ltd., Suwon-si (KR)

(21) Appl. No.: 13/833,987

(22) Filed: Mar. 15, 2013

(30) Foreign Application Priority Data
Apr. 26, 2012 (KR) 10-2012-0043900
Aug. 2, 2012 (KR) 10-2012-0084943

(51) Int. Cl. H01L 29/775; H01L 29/78

(52) U.S. Cl. CPC H01L 29/775; H01L 29/78; Y10S 977/742; B82Y 99/00
USPC 257/29; 257/288

(57) ABSTRACT

Provided is a field effect transistor including a drain region, a source region, and a channel region. The field effect transistor may further include a gate electrode on or surrounding at least a portion of the channel region, and a gate dielectric layer between the channel region and the gate electrode. A portion of the channel region adjacent the source region has a sectional area smaller than that of another portion of the channel region adjacent the drain region.

### CROSS-REFERENCE TO RELATED APPLICATIONS

This U.S. non-provisional patent application claims priority under 35 U.S.C. §119 to Korean Patent Application Nos. 10-2012-0043900 and 10-2012-0084943, filed on Apr. 26, 2012 and Aug. 2, 2012, respectively, in the Korean Intellectual Property Office, the entire contents of which are hereby incorporated by reference.

### BACKGROUND OF THE INVENTION

Example embodiments of the inventive concept relate to field effect transistors and methods of fabricating the same, and in particular, to field effect transistors having nano-sized channel regions and methods of fabricating the same.

The performance of CMOS devices for use in a digital circuit may depend on a channel switching speed and/or a channel controllability by a gate electrode. For an analog circuit, electric current can be changed by a relatively small variation of a gate voltage. As a pattern size of a two-dimensional transistor decreases, the strength of an electric field between source and drain regions may significantly increase, a hot carrier effect may be increased, and/or depletion regions from the source and drain regions may overlap with each other. As the result of the overlapping of the depletion regions, it may be difficult to control switching of the channel region using the electric field from the gate electrode. Further, there may be an increase in a size ratio of the depletion regions around the source and drain regions relative to a depletion region of the entire channel region. In the case where the ratio of the depletion region is relatively increased, a channel length may be decreased and a threshold voltage may be changed.

### SUMMARY

Example embodiments of the inventive concept provide a transistor with a channel region having a non-uniform cross-sectional area. The channel region may be shaped like a one-dimensional nano wire, and thus, the transistor can exhibit a reduced fluctuation in conductance and capacitance properties. In addition, since a hot carrier effect can be improved, a stable operation property and an improvement in operating performance can be achieved from the transistor.

Other example embodiments of the inventive concept provide a transistor with a suppressed hot carrier effect and an improved or optimized drain current.

According to some example embodiments of the inventive concepts, a field effect transistor includes a source region, a drain region, and a channel region extending between the source region and the drain region. A portion of the channel region adjacent the source region and a portion of the channel region adjacent the drain region have differing cross-sectional areas.

In example embodiments, the channel region may be a nanostructure having a dimension smaller than about 100 nm, smaller than about 50 nm, or smaller than about 20 nm.

In example embodiments, the cross-sectional area of the portion of the channel region adjacent the source region may be less than the cross-sectional area of the portion of the channel region adjacent the drain region.

In example embodiments, the portions of the channel region may directly contact the source and drain regions, respectively, such that the cross-sectional areas define respective contact areas between the channel region and the source and drain regions.

In example embodiments, a width of the channel region may continuously decrease between the drain region and the source region.

In example embodiments, the width of the channel region may monotonically decrease between the drain region and the source region.

In example embodiments, the channel region may be a carbon nanotube.

In example embodiments, the channel region may extend in a direction parallel to a substrate that includes the source and drain regions thereon.

In example embodiments, the channel region may extend in a direction perpendicular to a substrate that includes at least one of the source and drain regions thereon.

In example embodiments, the channel region may include a plurality of nanostructures extending between the source and drain regions.

According to example embodiments of the inventive concepts; a field effect transistor may include a drain region and a source region, a channel region connecting the drain region with the source region, a gate electrode on or surrounding at least a portion of the channel region, and a gate dielectric layer between the channel region and the gate electrode. A first portion of the channel region connected to the source region has a sectional area smaller than that of a second portion of the channel region connected to the drain region.

In example embodiments, the channel region has a sectional area that continuously decreases from the drain region to the source region.

In example embodiments, a diameter of the first portion may be about 20% to about 40% of that of the second portion.

In example embodiments, the first portion has a diameter of about 3 nm to about 5 nm, and the second portion has a diameter of about 12 nm to about 20 nm.

In example embodiments, the gate electrode surrounds the channel region and the channel region penetrates or extends through the gate electrode.

In example embodiments, the channel region has a circular or elliptical section.

In example embodiments, the transistor may further include a substrate provided below the channel region. The drain region and the source region may be spaced apart from each other in a direction substantially parallel to a top surface of the substrate.

In example embodiments, the gate electrode extends between the substrate and the channel region.

In example embodiments, the transistor may further include a substrate provided below the channel region. The drain region and the source region may be spaced apart from each other in a direction substantially perpendicular to a top surface of the substrate.

In example embodiments, the source region may be provided in an upper portion of the substrate.

In example embodiments, the channel region may include a plurality of channel regions.

According to example embodiments of the inventive concepts, a method of fabricating a field effect transistor may include forming a drain region, a source region, and a channel region on a substrate, and sequentially forming a gate dielectric layer and a gate electrode on the channel region. The channel region may be formed to have a sectional area continuously decreasing from the drain region to the source region.

In example embodiments, the forming of the drain region, the source region, and the channel region may include sequentially forming a sacrificial layer and an active layer on the substrate, patterning the active layer and the sacrificial layer to form a recess region, and removing a portion of the sacrificial layer exposed by the recess region.

In example embodiments, the method may further include performing a surface treatment on the patterned active layer.

In example embodiments, the forming of the drain region, the source region, and the channel region may include forming a source region in an upper portion of the substrate, forming an insulating layer on the substrate to have a contact hole exposing the source region, forming a spacer on a sidewall of the contact hole, forming a channel region in the contact hole provided with the spacer, and forming a drain region on the channel region.

### BRIEF DESCRIPTION OF THE DRAWINGS

Example embodiments will be more clearly understood from the following brief description taken in conjunction with the accompanying drawings. FIGS. 1 through 27 represent non-limiting, example embodiments as described herein.

FIGS. 1 and 2 are perspective and sectional views, respectively, of a field effect transistor according to example embodiments of the inventive concept.

FIGS. 3 through 7 are perspective views illustrating a method of fabricating a field effect transistor according to example embodiments of the inventive concept.

FIG. 8 is a sectional view taken along a line I-I′ of FIG. 7.

FIGS. 9 and 10 are perspective views illustrating a field effect transistor according to other example embodiments of the inventive concept and a method of fabricating the same.

FIGS. 11 through 15 are sectional views illustrating a method of fabricating a field effect transistor according to still other example embodiments of the inventive concept.

FIG. 16 is a perspective view of a field effect transistor according to still other example embodiments of the inventive concept.

FIGS. 17 and 18 are graphs showing characteristics of transconductance gₘ and drain conductance g_{d}, respectively, in a field effect transistor according to a comparative example.

FIGS. 19 and 20 are simulation graphs showing characteristics of quantum capacitance Cs and total capacitance Ct, respectively, of the field effect transistor according to the comparative example.

FIGS. 21 and 22 are simulation graphs showing characteristics of quantum capacitance Cs and total capacitance Ct, respectively, of the field effect transistor according to example embodiments of the inventive concept.

FIGS. 23 and 24 are graphs showing potential energy and electric field in channel regions of field effect transistors according to example embodiments of the inventive concept and the comparative example.

FIG. 25 is a schematic block diagram illustrating an example of memory systems including a semiconductor device according to example embodiments of the inventive concept.

FIG. 26 is a schematic block diagram illustrating an example of memory cards including the semiconductor devices according to example embodiments of the inventive concept.

FIG. 27 is a schematic block diagram illustrating an example of information processing systems including a semiconductor device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

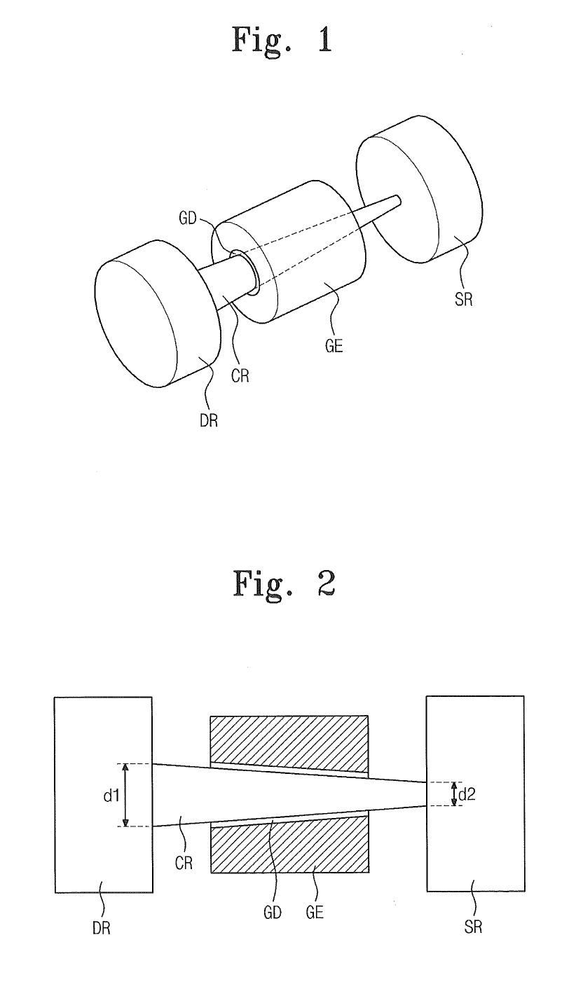

FIGS. 1 and 2 are perspective and sectional views, respectively, of a field effect transistor according to example embodiments of the inventive concept.

Referring to FIGS. 1 and 2, a field effect transistor according to example embodiments of the inventive concept may include a drain region DR, a source region SR, and a channel region CR connecting or extending between the drain region DR and the source region SR. The channel region CR may be formed to have a circular or elliptical cross-section, but example embodiments of the inventive concepts may not be limited thereto.

The channel region CR may be nanostructure, such as a nano wire or a nanotube, whose diameter ranges from several nanometers to several tens of nanometer. For example, the channel region CR may be a nano wire containing one of silicon (Si), germanium (Ge), silicon germanium (SiGe), gallium arsenide (GaAs), tungsten (W), cobalt (Co), platinum (Pt), zinc oxide (ZnO), and indium oxide (In₂O₃) or a carbon nanotube.

A gate electrode GE may be provided on or to surround at least a portion of the channel region CR. In example embodiments, the gate electrode GE may surround an outer circumference of the channel region CR, and the channel region CR may penetrate or extend through the gate electrode GE. The gate electrode GE may include doped silicon or a metallic material.

A gate dielectric layer GD may be provided between the channel region CR and the gate electrode GE. The gate dielectric layer GD may include at least one of silicon oxide, silicon nitride, silicon oxynitride, or a high-k material with a higher dielectric constant than that of silicon oxide.

The channel region CR has a non-uniform or differing sectional area in portions thereof between the source region SR and the drain region DR. In particular, as shown in FIGS. 1 and 2, a sectional area of the channel region CR is smaller near the source region SR than near the drain region DR. For example, a diameter of a portion of the channel region CR in contact with the source region SR may be about 20% to about 40% of that of another portion of the channel region CR in contact with the drain region DR. A second diameter d2 of the channel region CR in contact with the source region SR may be smaller than a first diameter d1 of the channel region CR in contact with the drain region DR. For example, the second diameter d2 may range from about 3 nm to about 5 nm, and the first diameter d1 may range from about 12 nm to about 20 nm. In other words, a contact area between the channel region CR and the source region SR is less than a contact area between the channel region CR and the drain region DR. In example embodiments, the channel region CR may be formed to have a width or sectional area that continuously decreases from the drain region DR to the source region SR. The width or sectional area of the channel region CR may be linearly or monotonically changed from the drain region DR to the source region SR. In certain embodiments, the sectional area of the channel region CR may be changed in some localized regions. Further, the channel region CR may include at least one portion having an increasing or constant sectional area in a direction from the drain region DR toward the source region SR.

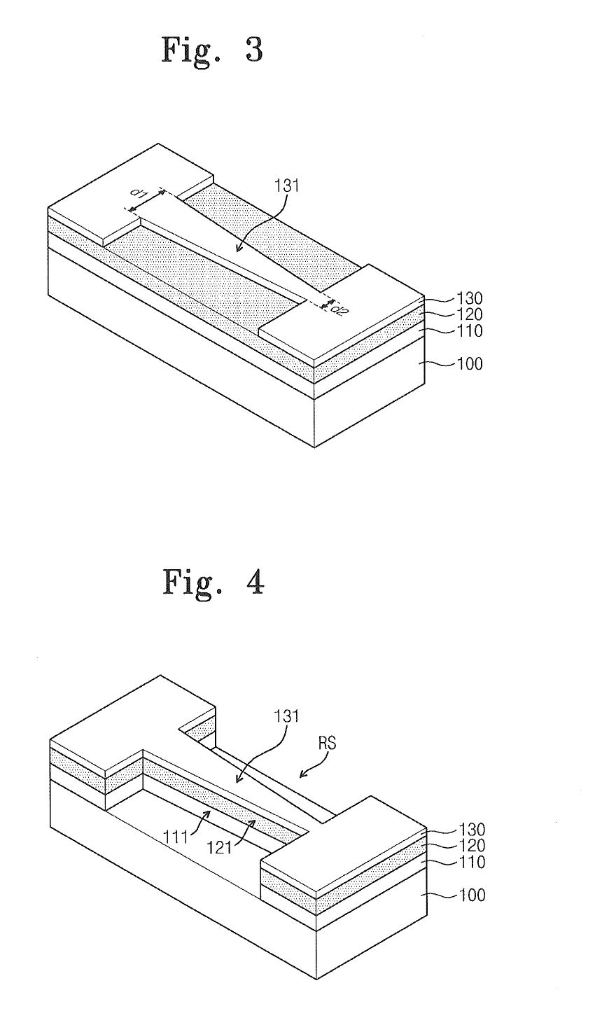

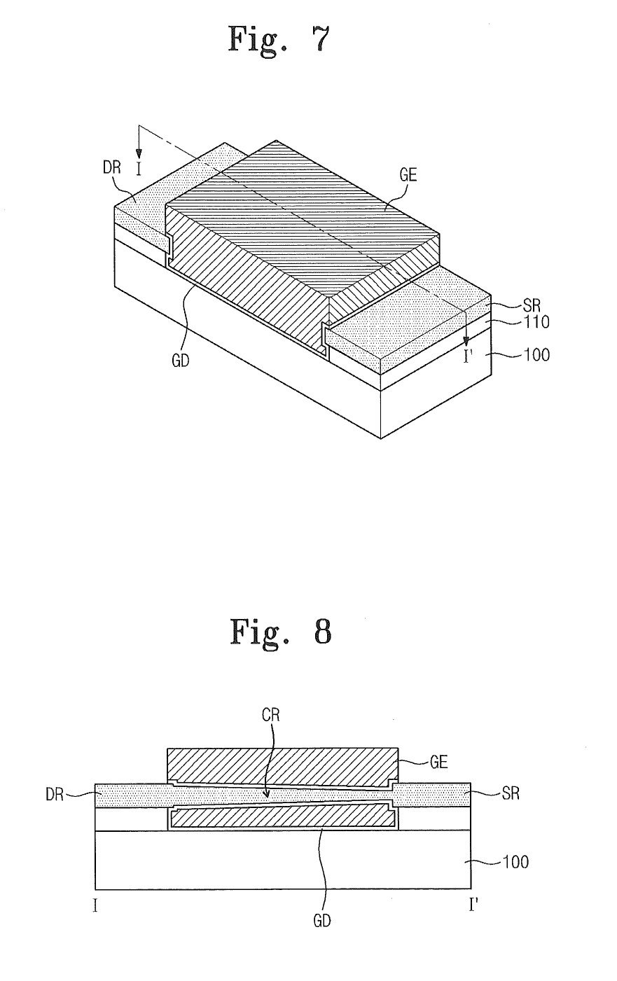

FIGS. 3 through 7 are perspective views illustrating a method of fabricating a field effect transistor according to example embodiments of the inventive concept, and FIG. 8 is a sectional view taken along a line I-I′ of FIG. 7. In the present embodiment, a field effect transistor may be formed in such a way that drain and source regions thereof are spaced apart from each other in a direction substantially parallel to a top surface of a substrate.

Referring to FIG. 3, a sacrificial layer 110, an active layer 120, and a mask pattern 130 may be sequentially formed on a substrate 100. In example embodiments, the substrate 100 may be a semiconductor wafer of silicon or germanium, a silicon-on-insulator (SOI) wafer. In other embodiments, the substrate 100 may be a plastic substrate including polyethylene terephthalate (PET) or polyvinylpyrrolidone (PVP) or a glass substrate. The sacrificial layer 110, the active layer 120, and the mask pattern 130 may be formed using, for example, a chemical vapor deposition (CVD) process, a sputtering process, and/or an atomic layer deposition (ALD) process.

In example embodiments, the active layer 120 may be a semiconductor layer containing at least one of Si, Ge, SiGe, or GaAs. The sacrificial layer 110 may include at least one of materials having an etch selectivity with respect to the active layer 120. For example, in the case where the active layer 120 is formed of a silicon layer, the sacrificial layer may be or include a silicon-germanium layer.

The mask pattern 130 may be a photoresist layer. The mask pattern 130 may include a line-shaped pattern 131 with end-portions having first and second widths d1 and d2, respectively. In example embodiments, the line-shaped pattern 131 may have a width continuously or monotonically decreasing from the first width d1 to the second width d2. In other embodiments, the line-shaped pattern 131 may include at least one portion, whose width is locally increased or constant in the direction with preserving the condition of d1>d2. Hereinafter, for the sake of brevity, the description that follows will refer to an example of the present embodiment in which the line-shaped pattern 131 has a continuously decreasing width, but example embodiments of the inventive concepts may not be limited thereto.

Referring to FIG. 4, the active layer 120 and the sacrificial layer 110 may be patterned using the mask pattern 130 an etch mask. The patterning process may include a dry and/or wet etching step. As the result of the patterning process, a line-shaped active pattern 121 and a line-shaped sacrificial pattern 111 may be formed to have substantially the same shape as that of the line-shaped pattern 131. In addition, as the result of the patterning process, a recess region RS may be formed to expose sidewalls of the line-shaped active pattern 121 and the line-shaped sacrificial pattern 111.

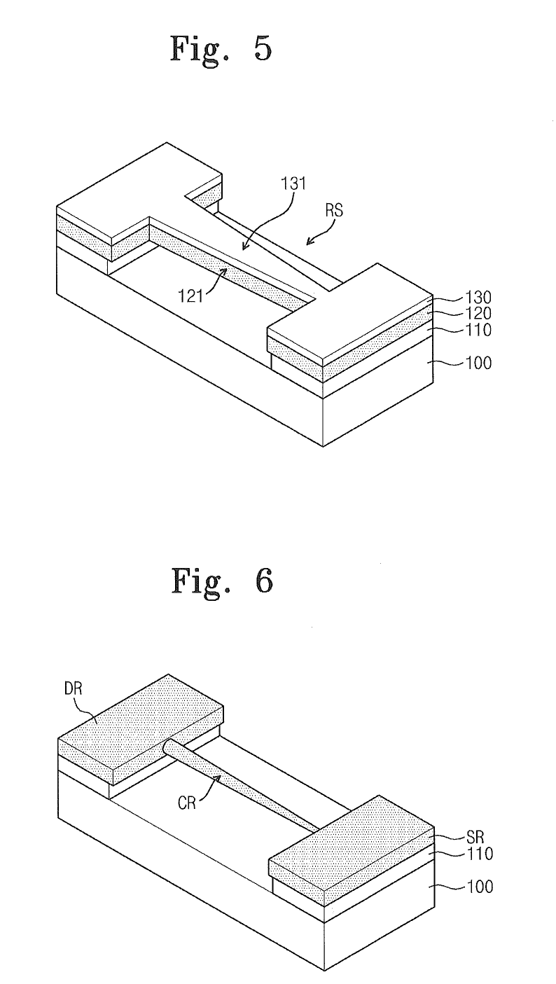

Referring to FIG. 5, the line-shaped sacrificial pattern 111 may be selectively removed, such that a bottom surface of the line-shaped active pattern 121 may be locally exposed. The removal of the line-shaped sacrificial pattern 111 may be performed using an etching solution or an etching gas capable of selectively removing the line-shaped sacrificial pattern 111 and suppressing the active layer 120 and the substrate 100 from being etched. For example, in the case where the line-shaped sacrificial pattern 111 contains silicon-germanium, a selective removal of the line-shaped sacrificial pattern 111 may be performed using an etching solution containing peracetic acid. The etching solution may further contain hydrofluoric acid and deionized water. Since the line-shaped sacrificial pattern 111 has a width narrower than other portions of the sacrificial layer 110, it is possible to prevent other portions of the sacrificial layer 110 near the line-shaped sacrificial pattern 111 from being excessively etched.

Referring to FIG. 6, the mask pattern 130 may be removed, and thereafter, a surface-treating process may be performed to the line-shaped active pattern 121. As the result of the surface-treating process, the line-shaped active pattern 121 may have a rounded channel region CR, as shown in FIG. 6, connecting a drain region DR and a source region SR. In example embodiments, the surface-treating process may include treating an exposed surface of the line-shaped active pattern 121 with HCl-containing gas and annealing it in an ambient of H₂. Accordingly, the channel region CR may be formed to have a circular or elliptical cross-section. Since the line-shaped pattern 131 has a decreasing width as described above, the channel region CR may be formed to have a continuously decreasing sectional area.

Referring to FIGS. 7 and 8, a gate dielectric layer GD and a gate electrode GE may be sequentially formed on the resultant structure provided with the channel region CR. The gate dielectric layer GD and the gate electrode GE may be formed by sequentially forming an dielectric layer and a conductive layer to surround at least a portion of the channel region CR, and then, patterning the dielectric layer and the conductive layer. In example embodiments, the gate dielectric layer GD may be formed of a silicon oxide layer, a silicon nitride layer, a silicon oxynitride layer, or a high-k material having a higher dielectric constant than that of silicon oxide. The gate electrode GE may be formed of a doped silicon layer or a metallic layer. The formation of the gate dielectric layer GD and the gate electrode GE may be performed using, for example, a thermal oxidation process, a CVD process, a sputtering process, and/or an ALD process.

According to example embodiments of the inventive concept, the channel region may be formed to extend horizontally, and a sectional area thereof may be smaller near the source region than near the drain region.

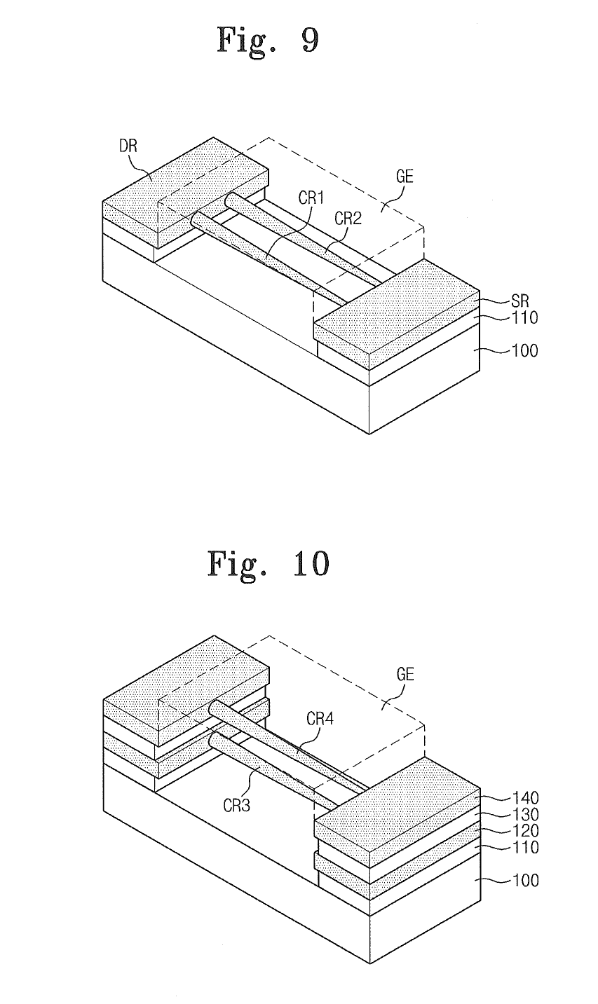

FIGS. 9 and 10 are perspective views illustrating a field effect transistor according to other example embodiments of the inventive concept and a method of fabricating the same. For convenience in description, the aforesaid technical features may be omitted below.

A plurality of the channel regions may be provided. For example, as shown in FIG. 9, the channel region may include a plurality of channel regions CR1 and CR2 connecting the drain region DR to the source region SR. The first channel region CR1 and the second channel region CR2 may be horizontally spaced apart from each other. The channel regions CR1 and CR2 may be formed by modifying the shape of the mask pattern 130 described with reference to FIG. 3. As shown in FIG. 10, the channel region may include a plurality of channel regions CR3 and CR4 vertically spaced apart from each other. The formation of the channel regions CR3 and CR4 may include alternatingly and repeatedly forming sacrificial layers 110 and 130 and active layers 120 and 140 on the substrate 100 and performing the process described with reference to FIGS. 3 through 8. Although, for the sake of brevity, the drawing shows two channel regions, the number of the channel regions in each or both of the horizontal and vertical directions will not be limited thereto.

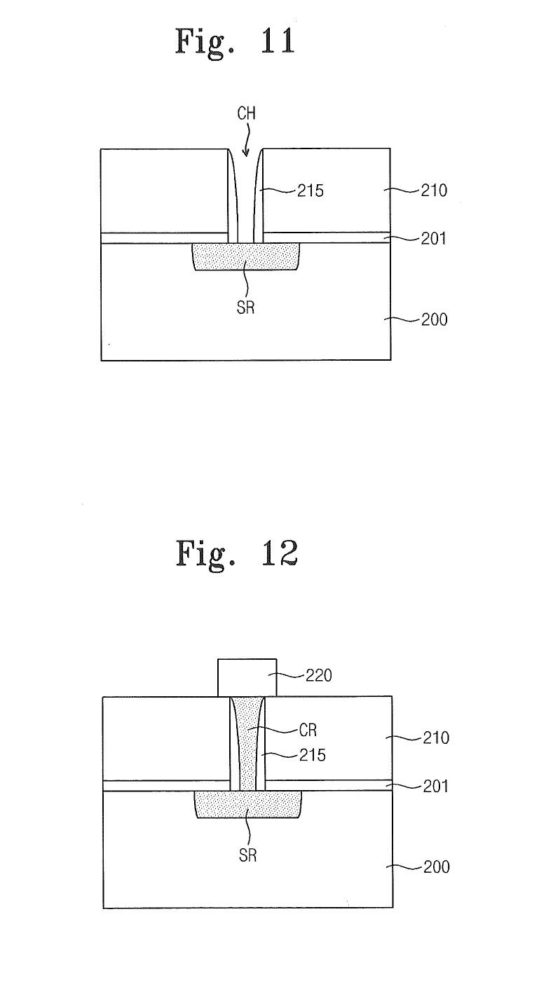

FIGS. 11 through 15 are sectional views illustrating a method of fabricating a field effect transistor according to still other example embodiments of the inventive concept. In the present embodiment, the field effect transistor may include a drain region and a source region spaced apart from each other in a direction substantially perpendicular to a top surface of the substrate.

Referring to FIG. 11, a first insulating layer 201 and a second insulating layer 210 may be sequentially formed on a substrate 200. For example, the first insulating layer 201 may include a silicon nitride layer, and the second insulating layer 210 may include a silicon oxide layer. In example embodiments, the substrate 200 may be a semiconductor wafer of silicon or germanium. A source region SR may be formed in an upper portion of the substrate 200. The source region SR may be a doped region having a different conductivity type from that of the substrate 200. In example embodiments, the source region SR may be formed before the formation of the first insulating layer 201. Alternatively, the source region SR may be formed through a subsequent implantation process, for example, after forming a channel hole CH.

The channel hole CH may be formed through the insulating layers 201 and 210 to expose the source region SR. The channel hole CH may be formed by a dry or wet etching process. The channel hole CH may be formed to have a circular or elliptical horizontal section. In example embodiments, a plurality of the channel holes CH may be formed on the substrate. A spacer 215 may be formed on a sidewall of the channel hole CH. The spacer 215 may include, for example, a silicon oxide layer. The formation of the spacer 215 may include forming a insulating layer on the second insulating layer 210 and performing a dry etching process to remain a portion of the insulating layer on the sidewall of the channel hole CH. A thickness and/or a width of the spacer 215 may increase with decreasing a distance from the substrate 200. Accordingly, the channel hole CH provided with the spacer 215 may have a downward decreasing diameter.

Referring to FIG. 12, a channel region CR may be formed to fill the channel hole CH. Due to the downward narrowing profile of the channel hole CH provided with the spacer 215, the channel region CR may be formed to have a downward decreasing sectional area. The channel region CR may include, for example, Si, Ge, SiGe, or GaAs. The channel region CR may be formed by an epitaxy process using the substrate 200 as a seed layer or by a deposition process. The channel region CR may be doped, in an in-situ manner, to have a different conductivity type from that of the source region SR. Alternatively, the channel region CR may be an undoped semiconductor. After the formation of the channel region CR, a mask pattern 220 may be formed to cover the channel region CR. In example embodiments, the mask pattern 220 may include a photoresist layer and/or a silicon nitride layer.

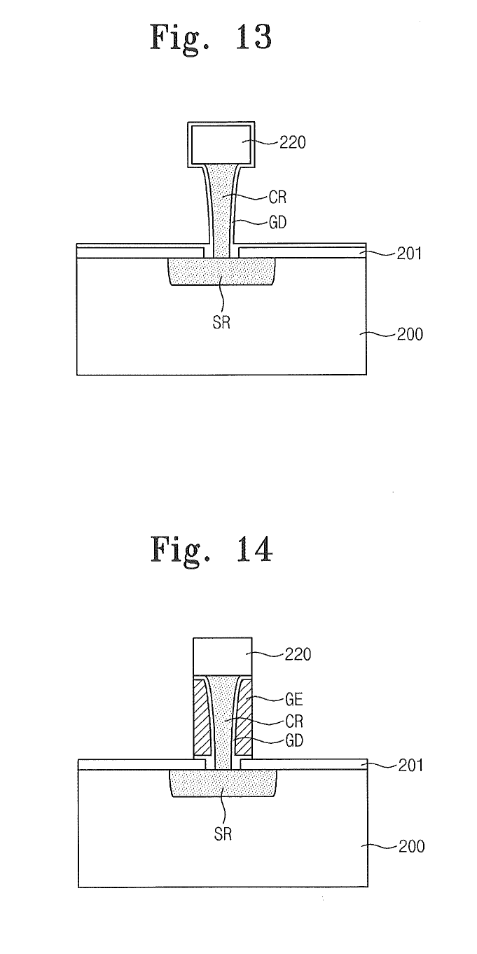

Referring to FIG. 13, the second insulating layer 210 and the spacer 215 may be selectively etched. In example embodiments, in the case where the second insulating layer 210 and the spacer 215 is a silicon oxide layer and the first insulating layer 201 is a silicon nitride layer, the selective etching process may be performed using an etching solution containing hydrofluoric acid (HF). After the selective etching process, a gate dielectric layer GD may be formed on the substrate 200. The gate dielectric layer GD may include at least one of silicon oxide, silicon nitride, silicon oxynitride, or high-k materials with a higher dielectric constant than that of silicon oxide. The gate dielectric layer GD may be formed using a CVD process, a thermal oxidation process, a sputtering process, and/or an ALD process.

Referring to FIG. 14, a gate electrode GE may be formed on the gate dielectric layer GD. The formation of the gate electrode GE may include forming a gate electrode layer on the gate dielectric layer GD and patterning the gate electrode layer using a dry or wet etching process, in which the mask pattern 220 is used as an etch mask. The first insulating layer 201 may be used as an etch stop layer in the etching process. In example embodiments, a portion of the gate dielectric layer GD may be etched during the formation of the gate electrode GE.

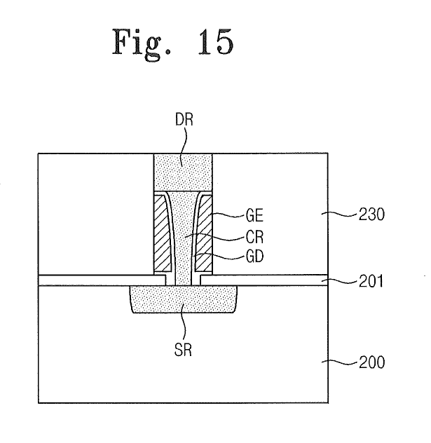

Referring to FIG. 15, an interlayer insulating layer 230 may be formed on the first insulating layer 201. A planarization process may be performed on the interlayer insulating layer 230 to expose a top surface of the mask pattern 220. The interlayer insulating layer 230 may include, for example, a silicon oxide layer. The mask pattern 220 exposed by the interlayer insulating layer 230 may be selectively removed to expose the channel region CR. For example, in the case where the mask pattern 220 includes the silicon nitride layer, the mask pattern 220 may be removed using an etching solution containing phosphoric acid (H₃PO₄). A drain region DR may be formed in a space formed by removing the mask pattern 220. The drain region DR may be formed of the same material as the substrate 200. The drain region DR may be formed using an epitaxy process or a deposition process. The drain region DR may be doped, for example, in an in-situ manner to have the same conductivity type as the source region SR.

According to the present embodiment, the channel region may be formed to extend vertically, and a sectional area thereof may be smaller near the source region than near the drain region.

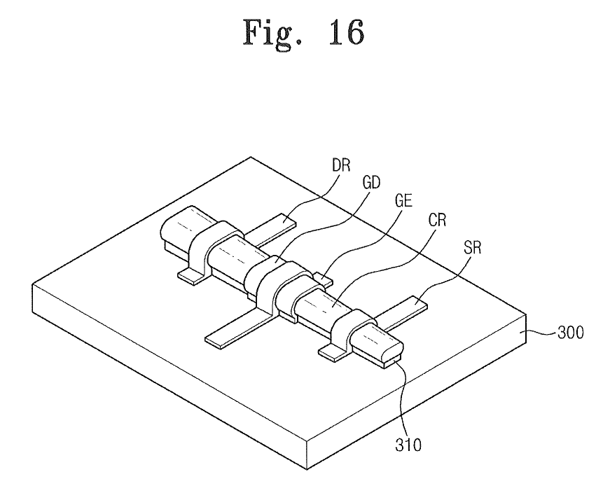

FIG. 16 is a perspective view of a field effect transistor according to still other example embodiments of the inventive concept. For convenience in description, the aforesaid technical features may be omitted below.

Referring to FIG. 16, a channel region CR may be provided to have a sectional area decreasing in a direction from a drain region DR to source region SR. The channel region CR may have, for example, an elliptical section. An intermediate layer 310 may be provided between the channel region CR and a substrate 300. The intermediate layer 310 may be formed of, for example, a silicon oxide layer and/or a silicon nitride layer. A gate electrode GE may be provided to surround a portion of the channel region CR. For example, the gate electrode GE may surround top and side surfaces of the channel region CR and the intermediate layer 310 may be in contact with a bottom surface of the channel region CR. In example embodiments, the gate electrode GE may have an omega-shaped (Ω) section. A gate dielectric layer GD may be provided between the gate electrode GE and the channel region CR. A source region SR and a drain region DR may be provided at opposing sides of the channel region CR, respectively, to cover at least a portion of the channel region CR.

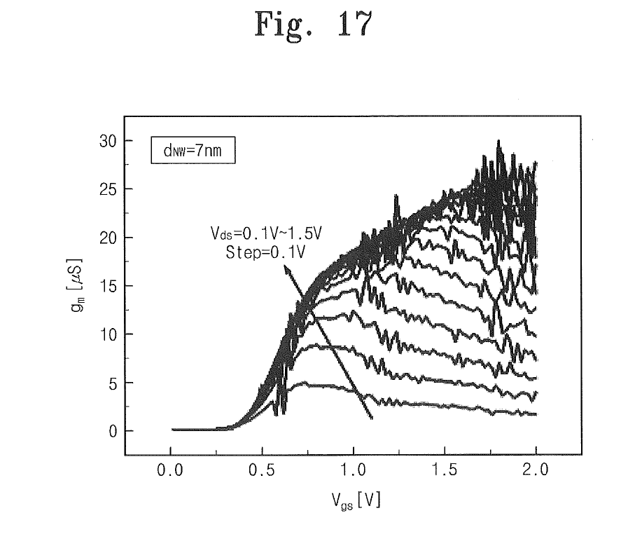

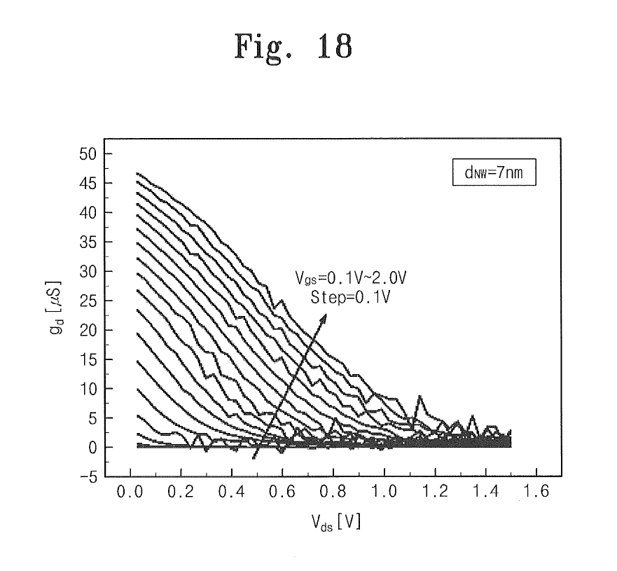

FIGS. 17 and 18 are graphs showing characteristics of transconductance gₘ and drain conductance g_{d}, respectively, in a field effect transistor according to a comparative example. The field effect transistor according to the comparative example was formed to have a channel region having a constant diameter (e.g., of 7 nm) (i.e., d_{NW}=7 nm) Transconductance gₘ was obtained by differentiating a drain electric current Id with respect to a gate-source voltage Vgs, and drain conductance g_{d} was obtained by differentiating the drain electric current Id with respect to a drain-source voltage Vds. In more detail, FIG. 17 shows transconductance gₘ measured as a function of gate-source voltage Vgs, for different drain-source voltages Vds from 0.1V to 1.5V with an increment of 0.1V. FIG. 18 shows drain conductance g_{d} measured as a function of drain-source voltage Vds, for different gate-source voltages Vgs from 0.1V to 2.0V with an increment of 0.1V. For the field effect transistor according to the comparative example, transconductance gₘ and drain conductance g_{d} thereof exhibited a plurality of fluctuation, as depicted in FIGS. 17 and 18.

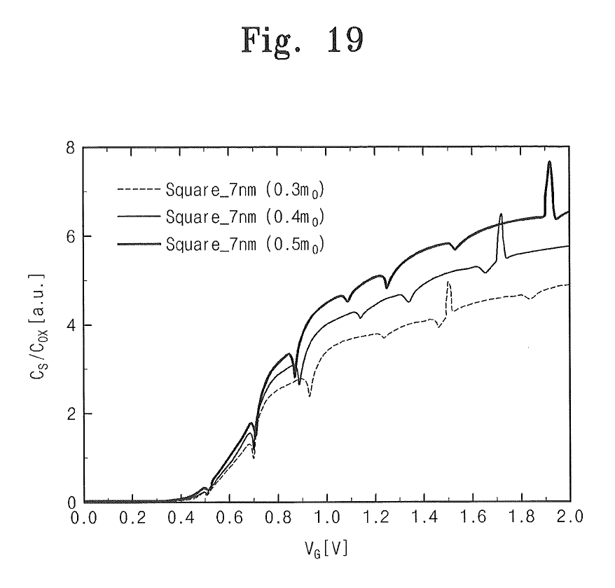

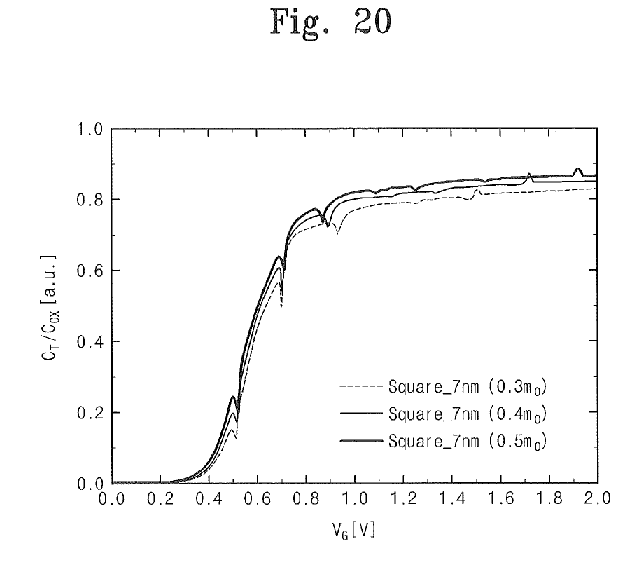

FIGS. 19 and 20 are simulation graphs showing characteristics of quantum capacitance Cs and total capacitance Ct, respectively, of the field effect transistor according to the comparative example. Curves in FIGS. 19 and 20 were obtained for effective masses of 0.3 m₀, 0.4 m₀, and 0.5 m₀, respectively. The quantum capacitance Cs was obtained by differentiating surface charge Qn with respect to gate voltage Vg and exhibited a plurality of saw-toothed fluctuation, as depicted in FIG. 19. The total capacitance Ct was calculated using the following equation.

1/Ct=1/Cox+1/Cs, [Equation 1]

where Ct denotes a total capacitance, Cox denotes a gate dielectric layer capacitance, and Cs denotes a quantum capacitance.

Since the total capacitance Ct is dependent on the quantum capacitance Cs, a plurality of saw-toothed fluctuation were found from a curve of the total capacitance Ct, but a width of the fluctuation was narrowed compared with that of the quantum capacitance Cs.

The fluctuation of the quantum capacitance Cs may occur because the channel region of the field effect transistor is provided in the form of nano wire having a one-dimensional density of state (DOS). For example, the nano wire may have quantized sub-levels, which may result in quantum capacitance Cs fluctuating with changing gate voltage Vg. The fluctuation of quantum capacitance Cs may result in fluctuations in total capacitance Ct, transconductance gₘ and drain conductance g_{d}, which may deteriorate stability in operation of a transistor or a circuit.

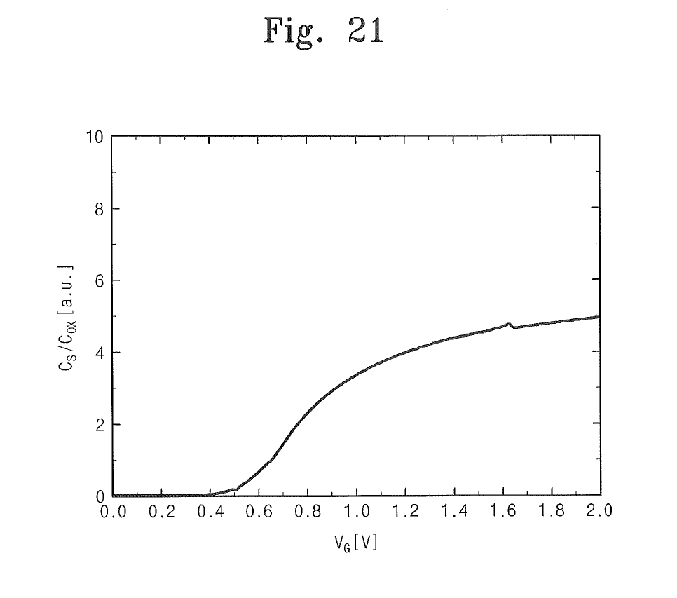

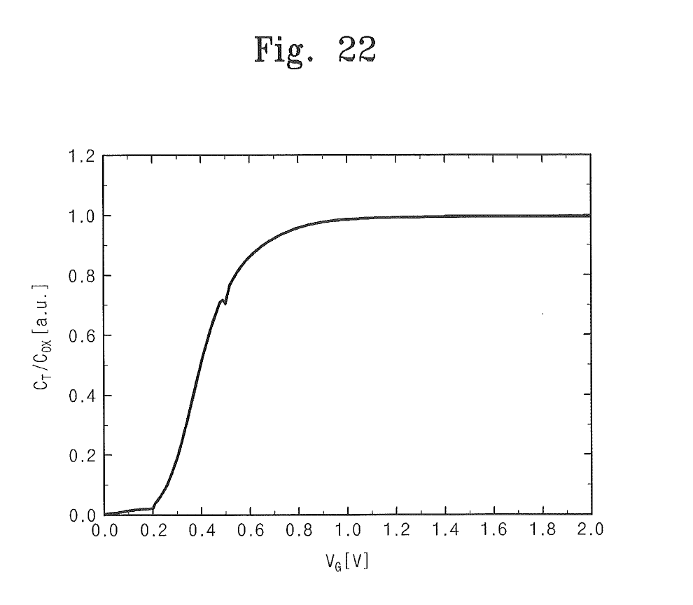

FIGS. 21 and 22 are simulation graphs showing characteristics of quantum capacitance Cs and total capacitance Ct, respectively, of the field effect transistor according to example embodiments of the inventive concept. In the simulation, a nano wire, serving as a channel region of the field effect transistor, was assumed to have a sectional area decreasing from the drain region gradually to the source region. In more detail, the nano wire was assumed to be 12 nm near a drain region and 3 nm near a source region.

According to example embodiments of the inventive concept, curves of the quantum capacitance Cs and the total capacitance Ct have substantially no fluctuation. This means that quantized sub-energy levels were transformed into continuously varying sub-energy level, as the result of the decreasing sectional area of the channel region. Further, this means that the transistor can have more stable operational characteristics.

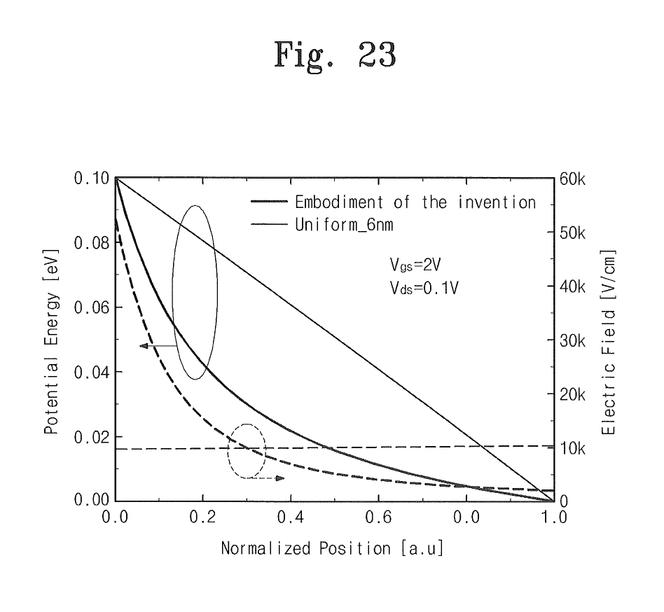

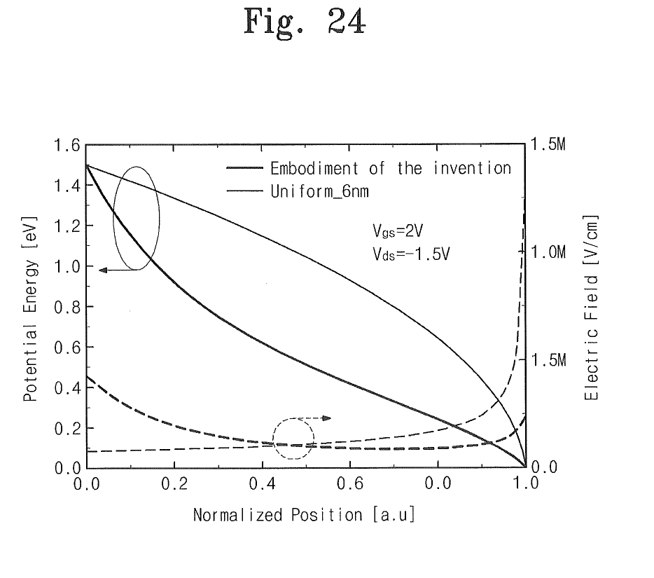

FIGS. 23 and 24 are graphs showing potential energy and electric field in channel regions of field effect transistors according to example embodiments of the inventive concept and the comparative example. FIG. 23 shows potential energy and electric field at a linear region (i.e., Vd<Vg−Vt), and FIG. 24 shows potential energy and electric field at a saturation region (i.e., Vd≧Vg−Vt). When a length of the channel region is normalized, the origin represents an end of the channel region adjacent to a source region and a position of 1.0 represents the other or opposite end of the channel region adjacent to a drain region. As shown in FIGS. 23 and 24, for the field effect transistor according to example embodiments of the inventive concept, the potential energy was drastically or exponentially reduced from the source region to the drain region, when compared with the case of the comparative example. This means that efficiency in ballistic transport of electron can be increased and a back scattering can be reduced. Accordingly, the transistor can have an increased drain current Id and an increased operation speed. Furthermore, as shown in FIG. 24, the electric field was weakened near the drain region (i.e., near the normalized position of 1.0). This means that a hot carrier effect can be effectively suppressed.

The inventive concept is not restricted to the aforementioned and illustrated embodiments, and modifications and changes can be made within the scope of the inventive concept defined in the following claims. For example, the features and configurations of the aforementioned embodiments may be exchanged or combined with each other within the scope of the inventive concept.

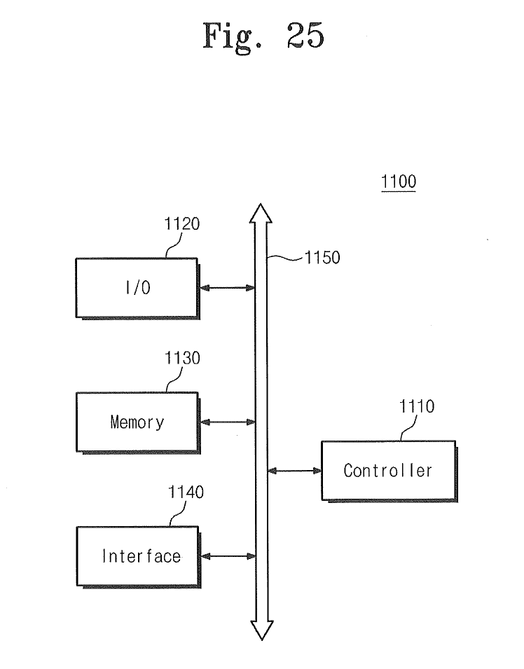

FIG. 25 is a schematic block diagram illustrating an example of memory systems including a semiconductor device according to example embodiments of the inventive concept.

Referring to FIG. 25, an electronic system 1100 according to example embodiments of the inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted. The memory device 1130 and/or the controller 1110 may include a semiconductor device according to example embodiments of the inventive concept.

The controller 1110 may include at least one of a microprocessor, a digital signal processor, a microcontroller, and/or another logic device. The other logic device may have a similar function to any one of the microprocessor, the digital signal processor and the microcontroller. The I/O unit 1120 may include a keypad, a keyboard, and/or a display unit. The memory device 1130 may store data and/or commands. The memory device 1130 may include at least one of the semiconductor devices according to the embodiments described above. The memory device 1130 may further include other types of semiconductor devices which are different from the semiconductor devices described above. The interface unit 1140 may transmit electrical data to a communication network or may receive electrical data from a communication network. The interface unit 1140 may operate wirelessly or by cable. For example, the interface unit 1140 may include an antenna for wireless communication or a transceiver for cable communication. Although not shown in the drawings, the electronic system 1100 may further include a fast DRAM device and/or a fast SRAM device that acts as an operating memory device for improving an operation of the controller 1110.

The electronic system 1100 may be used in or applied to a lap-top computer, a personal digital assistant (PDA), a portable computer, a web tablet, a wireless phone, a mobile phone, a digital music player, a memory card, and/or other electronic products. The electronic products may be configured to receive or transmit information data wirelessly.

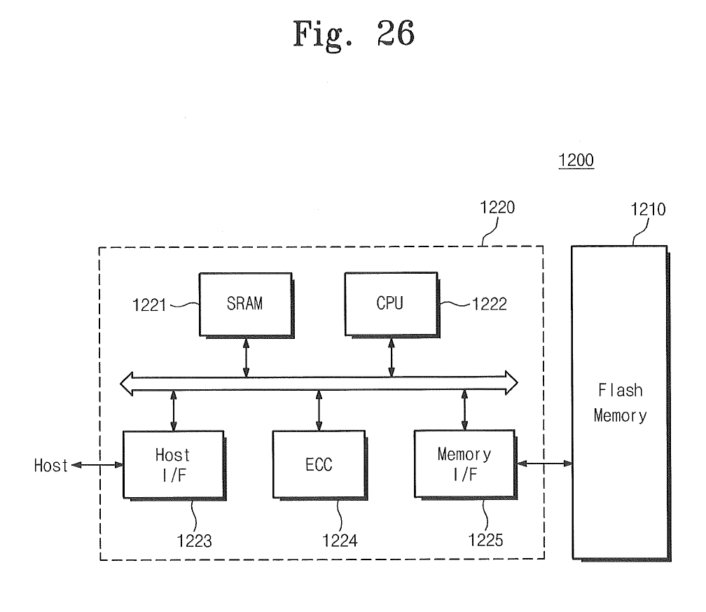

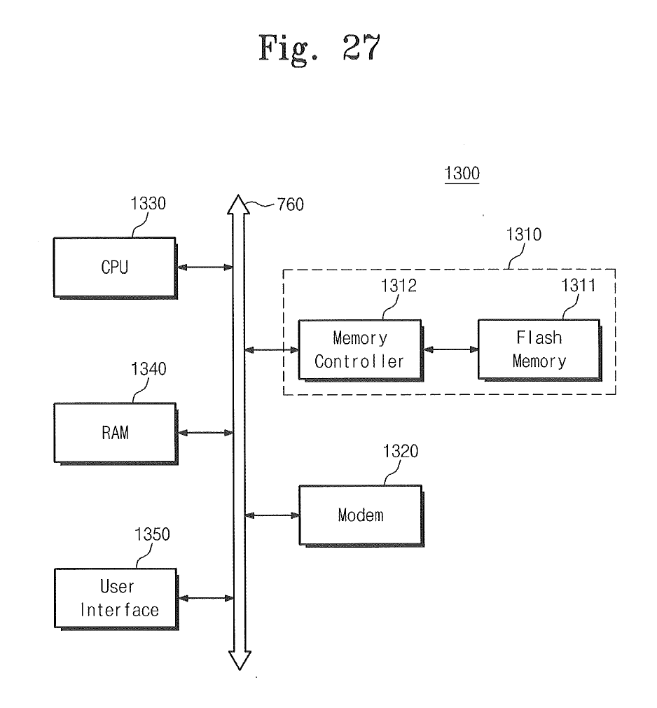

FIG. 26 is a schematic block diagram illustrating an example of memory cards including the semiconductor devices according to example embodiments of the inventive concept.

Referring to FIG. 26, a memory card 1200 may include a memory device 1210. In example embodiments, the memory device 1210 may include at least one of the semiconductor devices according to the various embodiments mentioned above. In other embodiments, the memory device 1210 may further include other types of semiconductor devices which are different from the semiconductor devices according to the embodiments described above. The memory card 1200 may include a memory controller 1220 that controls data communication between a host and the memory device 1210. The memory device 1210 and/or the controller 1220 may include a semiconductor device according to example embodiments of the inventive concept.

The memory controller 1220 may include a processing unit 1222 that controls overall operations of the memory card 1200. In addition, the memory controller 1220 may include an SRAM device 1221 used as an operation memory of the processing unit 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may replace hard disks of computer systems as solid state disks (SSD) of the computer systems.

FIG. 27 is a schematic block diagram illustrating an example of information processing systems including a semiconductor device according to example embodiments of the inventive concept.

Referring to FIG. 27, an information processing system 1300 includes a memory system 1310, which may include at least one of the semiconductor devices according to example embodiments of the inventive concept. The information processing system 1300 also includes a modem 1320, a central processing unit (CPU) 1330, a RAM 1340, and a user interface 1350, which may be electrically connected to the memory system 1310 via a system bus 760. The memory system 1310 may be configured to have the same or similar technical features as the memory system of FIG. 25. Data processed by the CPU 1330 and/or input from an outside or external source may be stored in the memory system 1310. Here, the memory system 1310 may be provided as a solid state drive SSD, and thus, the information processing system 1300 may be able to store reliably a large amount of data in the memory system 1310. This increase in reliability enables the memory system 1310 to conserve resources for error correction and realize a high speed data exchange function. Although not shown in the drawing, it will be apparent to those of ordinary skill in the art that the information processing system 1300 may be also configured to include an application chipset, a camera image processor (CIS), and/or an input/output device.

Furthermore, a semiconductor device or memory system according to example embodiments of the inventive concept or may be packaged in various kinds of ways. For example, the semiconductor device or memory system may be employed in a Package on Package (PoP), Ball Grid Array (BGA), Chip Scale Package (CSP), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), or Wafer-level Processed Stack Package (WSP).

According to example embodiments of the inventive concept, a channel region of a transistor may be formed to have a sectional area that is controlled to reduce fluctuation in transconductance (gₘ) drain conductance (g_{d}), and quantum capacitance (Cs). In addition, it is possible to improve and stabilize device characteristics (such as, a hot carrier effect).

While example embodiments of the inventive concepts have been particularly shown and described, it will be understood by one of ordinary skill in the art that variations in form and detail may be made therein without departing from the spirit and scope of the attached claims. In addition, example embodiments of the inventive concept can be applied to realize a part of a sensor (in particular, a nano bio-sensor). In this case, since the channel has a one-dimensional structure whose a ratio of a surface area to a volume is high, fluctuation in conductance can be suppressed, as described above. Accordingly, it is possible to improve performance of the sensor.

1. A field effect transistor, comprising:
a drain region and a source region;
a channel region connecting the drain region with the source region;
a gate electrode on at least a portion of the channel region; and
a gate dielectric layer between the channel region and the gate electrode,
wherein a first portion of the channel region connected to the source region has a sectional area smaller than that of a second portion of the channel region connected to the drain region.

2. The field effect transistor of claim 1, wherein the channel region has a sectional area that continuously decreases from the drain region to the source region.

3. The field effect transistor of claim 1, wherein a diameter of the first portion is about 20% to about 40% of that of the second portion.

4. The field effect transistor of claim 1, wherein the first portion has a diameter of about 3 nanometers (nm) to about 5 nm, and wherein the second portion has a diameter of about 12 nm to about 20 nm.

5. The field effect transistor of claim 1, wherein the gate electrode surrounds the channel region and the channel region extends through the gate electrode.

6. The field effect transistor of claim 1, wherein the channel region has a circular or elliptical cross-section.

7. The field effect transistor of claim 1, further comprising a substrate below the channel region,
wherein the drain region and the source region are spaced apart from each other in a direction substantially parallel to a surface of the substrate.

8. The field effect transistor of claim 7, wherein the gate electrode extends between the substrate and the channel region.

9. The field effect transistor of claim 1, further comprising a substrate below the channel region,
wherein the drain region and the source region are spaced apart from each other in a direction substantially perpendicular to a surface of the substrate.

10. The field effect transistor of claim 9, wherein the source region is provided in an upper portion of the substrate.

11. The field effect transistor of claim 1, wherein the channel region comprises a plurality of channel regions.

12-15. (canceled)

16. A field effect transistor, comprising:
a source region;
a drain region; and
a channel region extending between the source region and the drain region, wherein a portion thereof adjacent the source region and a portion thereof adjacent the drain region have differing cross-sectional areas.

17. The transistor of claim 16, wherein the channel region is a nanostructure, and wherein the cross-sectional area of the portion thereof adjacent the source region is less than the cross-sectional area of the portion thereof adjacent the drain region.

18. The transistor of claim 17, wherein the portions of the channel region directly contact the source and drain regions, respectively.

19. The transistor of claim 16, wherein a width of the channel region continuously decreases between the drain region and the source region.

20. The transistor of claim 19, wherein the width of the channel region monotonically decreases between the drain region and the source region.

21. The transistor of claim 16, wherein the channel region comprises a carbon nanotube.

22. The transistor of claim 16, wherein the channel region extends in a direction parallel to a substrate, wherein the substrate includes the source and drain regions thereon.

23. The transistor of claim 16, wherein the channel region extends in a direction perpendicular to a substrate, wherein the substrate includes at least one of the source and drain regions thereon.

24. The transistor of claim 16, wherein the channel region comprises one of a plurality of channel regions extending between the source and drain regions.
